(19) United States
(12) Patent Application Publication
(10) Pub. No.: US 2026/0122773 A1
(43) Pub. Date: Apr. 30, 2026

(54) PRINTED CIRCUIT BOARD

(71) Applicant: SAMSUNG ELECTRO-MECHANICS CO., LTD., Suwon-si (KR)

(72) Inventor: In Gun KIM, Suwon-si (KR)

(73) Assignee: SAMSUNG ELECTRO-MECHANICS CO., LTD., Suwon-si (KR)

(21) Appl. No.: 19/171,814

(22) Filed: Apr. 7, 2025

(30) Foreign Application Priority Data
Oct. 31, 2024 (KR) 10-2024-0152703

(51) Int. Cl. H05K 1/02; H05K 1/03; H05K 1/11

(52) U.S. Cl. CPC H05K 1/0271; H05K 1/0306; H05K 1/111; H05K 1/115

(57) ABSTRACT

A printed circuit board including: a glass layer including a first region and a second region, surrounding the first region; a plurality of first metal vias spaced apart from each other in the first region and respectively including a first via portion penetrating through the glass layer; and a plurality of second metal vias spaced apart from each other in the second region and respectively including a second via portion penetrating through the glass layer, wherein the first via portion may have a maximum width smaller than the second via portion in a cross-section.

### CROSS-REFERENCE TO RELATED APPLICATION(S)

This application claims benefit of priority to Korean Patent Application No. 10-2024-0152703 filed on Oct. 31, 2024, in the Korean Intellectual Property Office, the disclosure of which is incorporated herein by reference in its entirety.

### TECHNICAL FIELD

The present disclosure relates to a printed circuit board.

In order to respond to the high performance and miniaturization strategy of semiconductors, the level of miniaturization and high densification required for a printed circuit board has increased. For example, in order to manufacture high-end products such as server boards, high-layering and large bodies are required. However, as the number of wiring layers increases and the body size increases, the board may become vulnerable to warpage. To solve this problem, the use of glass cores has been considered.

### SUMMARY

One of the various aspects of the present disclosure is to provide a printed circuit board that may increase process capability and design freedom with respect to metal vias formed in a glass layer.

One of the various solutions of the present disclosure is to form a fine metal via in a central region of a glass layer, which is a signal concentration region and/or an electronic component mounting region, and to form a metal via in a peripheral region of the glass layer in a form focusing on heat dissipation or power transmission.

For example, a printed circuit board according to an example embodiment may include: a glass layer including a first region, and a second region surrounding the first region; a plurality of first metal vias spaced apart from each other in the first region and respectively including a first via portion penetrating through the glass layer; and a plurality of second metal vias spaced apart from each other in the second region and respectively including a second via portion penetrating through the glass layer, and in a cross-section of the printed circuit board, the first via portion may have a maximum width that is smaller than a maximum width of the second via portion.

For example, a printed circuit board according to an example embodiment may include: a glass layer including a first region, and a second region surrounding the first region; a first metal via disposed in the first region, and including a first via portion penetrating through the glass layer, a first-first pad portion disposed on a first surface of the glass layer, and a first-second pad portion disposed on a second surface of the glass layer; and a second metal via disposed in the second region, including a second via portion penetrating through the glass layer, a second-first pad portion disposed on the first surface of the glass layer, and a second-second pad portion disposed on the second surface of the glass layer, and in a cross-section of the printed circuit board, the first-first pad portion may have a maximum width that is smaller than a maximum width of the second-first pad portion.

One of the various effects of the present disclosure is to provide a printed circuit board that may increase process capability and design freedom with respect to a metal via formed in a glass layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 is a plan view schematically illustrating a glass layer of the printed circuit board of FIG. 2 when viewed from above;

FIG. 4 is a cross-sectional view schematically illustrating another example of a printed circuit board;

FIG. 5 is a plan view schematically illustrating a glass layer of the printed circuit board of FIG. 4 when viewed from above;

FIG. 6 is a cross-sectional view schematically illustrating another example of a printed circuit board; and

FIG. 7 is a plan view schematically illustrating a glass layer of the printed circuit board of FIG. 6 when viewed from above.

### DETAILED DESCRIPTION

Hereinafter, the present disclosure will be described with reference to the accompanying drawings. In the drawings, the shape and size of the elements may be exaggerated or reduced for clearer description.

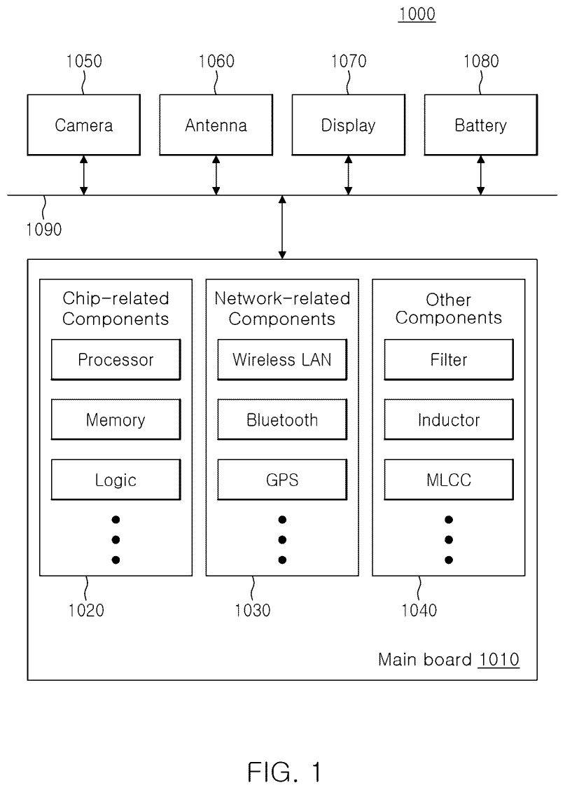

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component, and a server. However, the electronic device 1000 is not limited thereto, and may be any other electronic device that processes data in addition thereto.

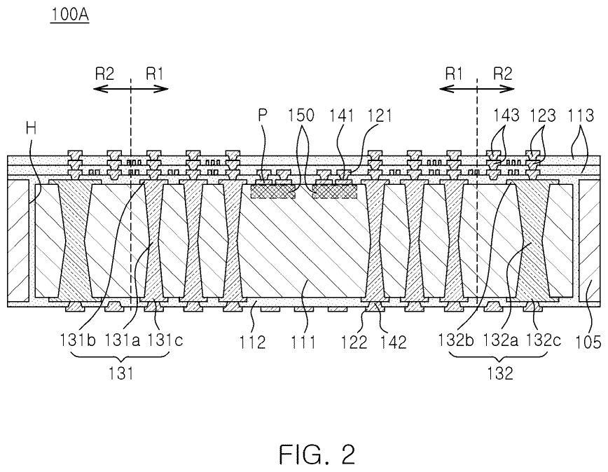

FIG. 2 is a cross-sectional view schematically illustrating an example of a printed circuit board.

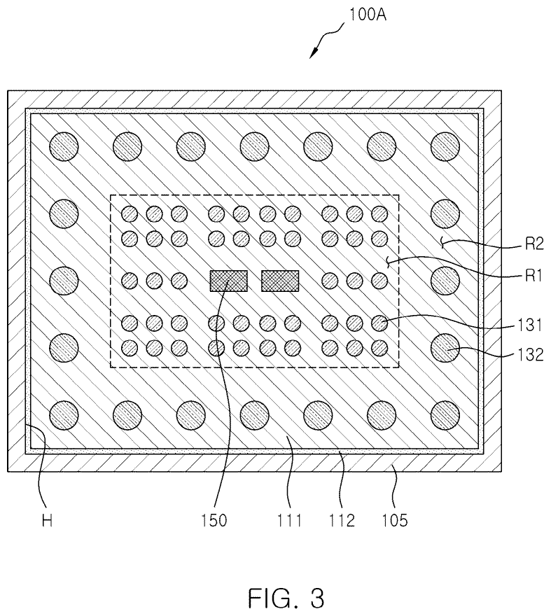

FIG. 3 is a plan view schematically illustrating a glass layer of the printed circuit board of FIG. 2 when viewed from above.

Referring to the drawings, a printed circuit board 100A according to an example embodiment may include a glass layer 111 including a first region R1 and a second region R2 surrounding the first region R1, a plurality of first metal vias 131 spaced apart from each other in the first region R1 and respectively including a first via portion 131a penetrating through the glass layer 111, and a plurality of second metal vias 132 spaced apart from each other in the second region R2 and respectively including a second via portion 132a penetrating through the glass layer 111. The first region R1 may include a portion adjacent to a center of the glass layer 111, and the second region R2 may include a portion adjacent to an edge of the glass layer 111. For example, the first region R1 may correspond to a central region of the glass layer 111, and the second region R2 may correspond to a peripheral region of the glass layer 111.

In this case, the first via portion 131a may have a smaller maximum width than the second via portion 132a in the cross-section. For example, the first via portion 131a may have a maximum width (or diameter) of 60 μm or less, and the second via portion 132a may have a maximum width (or diameter) of 100 μm or more. Here, the maximum width (or diameter) of each via portion in the cross-section may be measured, for example, using a scanning microscope or an optical microscope based on a cross-section obtained by vertically polishing or cutting a substrate, and a cut cross-section may be a cross-section obtained by cutting a central axis of each via portion. For example, in a signal concentration region, a denser design may be required, so that a plurality of first metal vias 131 having a small size may be formed in the first region R1. For example, each of the plurality of first metal vias 131 may include a metal via for signal transmission. On the other hand, in other regions, a design concentrating on heat dissipation characteristics or power transmission rather than density may be required, so that a plurality of second metal vias 132 having a large size may be formed in the second region R2. For example, each of the plurality of second metal vias 132 may include a metal via for power transmission or a metal via for heat dissipation. Here, the metal via for power transmission may also function as a metal via for heat dissipation. Therethrough, the process capability may be improved. Additionally, a high degree of design freedom may be obtained.

From this perspective, an average pitch between the plurality of first metal vias 131 may be smaller than an average pitch between the plurality of second metal vias 132. Here, the average pitch between the metal vias may be measured, for example, using a scanning microscope or an optical microscope based on the cross-section obtained by polishing or cutting the substrate in the vertical direction, and may use an average value of pitches between adjacent metal vias. In this case, as described above, in the signal concentration region, a denser design may be easier, and in other regions, a design concentrating on heat dissipation characteristics or power transmission rather than density may be easier.

Meanwhile, each of the plurality of first metal vias 131 may further include a first-first pad portion 131b disposed on an upper surface (first surface) of the glass layer 111 and a first-second pad portion 131c disposed on a lower surface (second surface) of the glass layer 111. The first via portion 131a of each of the plurality of first metal vias 131 may connect the first-first and first-second pad portions 131b and 131c of each of the plurality of first metal vias 131, which may be integrated with each other without a boundary, but the present disclosure is not limited thereto. Additionally, the plurality of second metal vias 132 may further include a second-first pad portion 132b disposed on the upper surface of the glass layer 111, and a second-second pad portion 132c disposed on the lower surface (second surface) of the glass layer 111. The second via portion 132a of each of the plurality of second metal vias 132 may connect the second-first and second-second pad portions 132b and 132c of each of the plurality of second metal vias 132, which may be integrated with each other without a boundary, but the present disclosure is not limited thereto. In this manner, when a pad portion is included, the reliability of connection with other connection vias may be improved.

In this case, a maximum width (or diameter) of the first-first pad portion 131b may be smaller than that of the second-first pad portion 132b in the cross-section. Additionally, a maximum width (or diameter) of the first-second pad portion 131c may be smaller than that of the second-second pad portion 132c in the cross-section. Here, the maximum width (or diameter) of each pad portion in the cross-section may be measured, for example, using a scanning microscope or an optical microscope based on the cross-section obtained by polishing or cutting the substate in the vertical direction, and the cut cross-section may be a cross-section obtained by cutting the central axis of each pad portion. In this case, as described above, a denser design may be easier in the signal concentration region, and in other regions, the design concentrating on heat dissipation characteristics or power transmission rather than density may be easier.

From this perspective, the first-first pad portion 131b may have a smaller planar area than the first-second pad portion 131c. Additionally, the first-second pad portion 131c may have a smaller planar area than the second-second pad portion 132c. Here, the planar area of each pad portion may be measured, for example, using a microscope or an optical microscope based on the cross-section obtained by polishing or cutting the substrate in a horizontal direction. Other methods and/or tools appreciated by one of ordinary skill in the art, even if not described in the present disclosure, may also be used. In this case, as described above, a denser design may be easier in the signal concentration region, and in other regions, the design concentrating on heat dissipation characteristics or power transmission rather than density may be easier.

Meanwhile, the printed circuit board 100A according to an example embodiment may further include an electronic component 150 embedded in the first region R1 of the glass layer 111, if necessary. A plurality of first metal vias 131 may be respectively disposed around the electronic component 150. For example, a plurality of first metal vias 131 may be concentratedly disposed in a region in which the electronic component 150 is embedded. Meanwhile, the embedding of the electronic component 150 may be achieved, for example, by forming a blind cavity or a through-cavity in the glass layer 111, disposing the electronic component 150 in the cavity, and then covering the electronic component 150 with an insulating material, but the present disclosure is not limited thereto. Meanwhile, the electronic component 150 may be provided in plural, each of which may have a connection pad P. A plurality of electronic components 150 may be embedded together in a single cavity, or may be embedded separately in each cavity.

Meanwhile, a printed circuit board 100A according to an example embodiment may include, if necessary, a frame 105 having a through-portion H in which at least a portion of a glass layer 111 is disposed, a first insulating layer 112 covering upper surfaces (first surfaces) and lower surfaces (second surfaces) of each of the frame 105 and the glass layer 111 and filling a space between the frame 105 and the glass layer 111 in the through-portion H, a first wiring layer 121 disposed on an upper surface (first surface) of the first insulating layer 112, a first via layer 141 including a plurality of first connection vias penetrating through an upper side (first side) of the first insulating layer 112 and connecting the first wiring layer 121 to a plurality of first and second metal vias 131 and 132 and a connection pad P of an electronic component 150, respectively, a second wiring layer 122 disposed on a lower surface (second surface) of the first insulating layer 112, and a second via layer 142 including a plurality of second connection vias penetrating through a lower side (second side) of the first insulating layer 112 and connecting the second wiring layer 122 to the plurality of first and second metal vias 131 and 132, respectively.

In this manner, the printed circuit board 100A according to an example embodiment may further include a frame 105 having a through-portion H, through which the process warpage may be more easily controlled. Additionally, the frame 105 may be provided on a panel level, and in this case, a plurality of printed circuit board 100A units may be manufactured in a single process using the frame 105 as a jig, and a plurality of unit boards may be obtained through a singulation process. Additionally, the frame 105 and the glass layer 111 may be surrounded through the first insulating layer 112 and the through-portion H may be filled, thereby achieving a stress relief effect. Additionally, the freedom of a wiring design may be increased by forming the first and second wiring layers 121 and 122 on the first and second insulating layers 112a and 112b. Additionally, an electrical connection path may be provided in the substrate through the first and second via layers 141 and 142.

Meanwhile, the printed circuit board 100A according to an example embodiment may further include, if necessary, a plurality of second insulating layers 113 disposed on the upper surface (first surface) of the first insulating layer 112, a plurality of third wiring layers 123 respectively disposed on upper surfaces (first surfaces) of the plurality of second insulating layers 113, and a plurality of third via layers 143 respectively penetrating through the plurality of second insulating layers 113 and respectively connected to one or more of the plurality of third wiring layers 123.

In this manner, the printed circuit board 100A according to an example embodiment may have a multilayer substrate structure in which a build-up layer is further formed on an upper side of the glass layer 111. For example, the printed circuit board 100A according to an example embodiment may be an interposer substrate having an asymmetrical structure. However, the present disclosure is not limited thereto, and, if necessary, the build-up layers may be formed on both the upper side and the lower side of the glass layer 111, but may be formed in an asymmetrical form. Alternatively, if necessary, the build-up layer may be further formed on the lower side of the glass layer 111. In this case, the printed circuit board 100A according to an example embodiment may be a package substrate on which a semiconductor chip is mounted. The package substrate may be a large-area substrate used for a server, or the like.

Hereinafter, the components of the printed circuit board 100A according to an example embodiment will be described in more detail with reference to the drawings.

The frame 105 may include a material having excellent rigidity, and may include, for example, Copper Clad Laminate (CCL) or Unclad CCL, but the present disclosure is not limited thereto. For example, the frame 105 may include other organic materials having excellent rigidity, or may include other types of inorganic materials having excellent rigidity. The frame 105 may be used as a jig during the process, and thus, the process may be performed on the panel level through the frame 105. Additionally, the frame 105 may be remain in a final unit after singulation, which may be more advantageous for wedge control.

The glass layer 111 may include glass, which is amorphous solid. The glass may include, for example, pure silicon dioxide (about 100% SiO₂), soda lime glass, borosilicate glass, alumino-silicate glass, etc. However, the present disclosure is not limited thereto, and alternative glass materials, such as fluorine glass, phosphate glass, and chalcogen glass, may also be used as materials of the glass layer 111. Additionally, other additives may be further included to form glass having specific physical properties. These additives may include not only calcium carbonate (e.g., lime) and sodium carbonate (e.g., soda), but also magnesium, calcium, manganese, aluminum, lead, boron, iron, chromium, potassium, sulfur, and antimony, and carbonates and/or oxides of these elements and other elements. Meanwhile, the glass layer 111 may be distinguished from an organic insulating material including glass fiber (Glass Fiber, Glass Cloth or Glass Fabric), for example, Copper Clad Laminate (CCL), Prepreg (PPG), or the like. The glass layer 111 may be in the form of, for example, a glass plate.

Each of the first and second insulating layers 112 and 113 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) together the resin. For example, the organic insulating material may include Prepreg (PPG), Ajinomoto Build-up Film (ABF), Photoimageable Dielectric (PID), and Bonding Sheet (BS), but the present disclosure is not limited thereto. The first and second insulating layers 112 and 113 may include substantially the same material, but the present disclosure is not limited thereto, and may include different materials. The second insulating layer 113 may be formed with a greater number of layers or a smaller number of layers than those illustrated in the drawing.

Each of the first to third wiring layers 121, 122 and 123 may include a metal. The metal may include copper (Cu), aluminum (Al), silver (Ag), tin (Sn), gold (Au), nickel (Ni), lead (Pb), titanium (Ti), and/or alloys thereof. For example, each of the first to third wiring layers 121, 122 and 123 may include chemical copper formed by electroless plating, as a seed layer, and may include electrolytic copper formed by electrolytic plating based thereon, as a pattern plating layer. Each of the first to third wiring layers 121, 122 and 123 may perform various functions according to the design. For example, the first to third wiring layers 121, 122 and 123 may include a signal pattern, a power pattern, and a ground pattern. Each of the patterns may have various shapes such as a line, a trace, a plane, and a pad. The pad may be a concept including a land. The third wiring layer 123 may be formed with a greater number of layers than those illustrated in the drawing, or may be formed with a smaller number of layers.

Each of the first and second metal vias 131 and 132 may include a metal. The metal may include copper (Cu), aluminum (Al), silver (Ag), tin (Sn), gold (Au), nickel (Ni), lead (Pb), titanium (Ti), and/or alloys thereof. For example, each of the first and second metal vias 131 and 132 may include a stack structure of a titanium layer and a copper layer formed by sputtering and/or electroless plating, as a seed layer. For example, the first and second metal vias 131 and 132 may include sputtered titanium and sputtered copper, sputtered titanium and chemical copper, or sputtered titanium, sputtered copper, and chemical copper. Additionally, a copper layer formed by electrolytic plating based thereon may be included as a plating layer. For example, the first and second metal vias 131 and 132 may include electrolytic copper. The first metal via 131 may include a metal via for signal transmission. The second metal via 132 may include a metal via for power transmission and/or heat dissipation. The first and second via portions 131a and 132a of each of the first and second metal vias 131 and 132 may have a shape in which side surfaces are tapered, for example, an hourglass shape, but are not limited thereto, and may have a cylindrical shape in which side surfaces are approximately vertical. The first-first, first-second, second-first, and second-second pad portions 131b, 131c, 132b and 132c of each of the first and second metal vias 131 and 132 may have a circular or elliptical shape on a plane, but are not limited thereto, and may have a polygonal shape if necessary. The first and second metal vias 131 and 132 may be provided in plural, respectively.

Each of the first to third via layers 141, 142 and 143 may include a metal. The metal may include copper (Cu), aluminum (Al), silver (Ag), tin (Sn), gold (Au), nickel (Ni), lead (Pb), titanium (Ti), and/or alloys thereof. For example, each of the first to third via layers 141, 142 and 143 may include chemical copper formed by electroless plating, as a seed layer, and may include electrolytic copper formed by electrolytic plating based thereon, as a pattern plating layer. Each of the first to third via layers 141, 142 and 143 may perform various functions according to the design. For example, the first to third via layers 141, 142 and 143 may include a signal via, a power via, and a ground via. Each of the first to third via layers 141, 142 and 143 may include a filled VIA in which a via hole is filled with metal, but may also include a conformal VIA in which the metal is disposed along a wall surface of the via hole. Each of the first to third via layers 141, 142 and 143 may have a tapered shape. Each of the first to third via layers 141, 142 and 143 may include a plurality of connecting vias. The third via layer 143 may be formed with a greater number of layers or a smaller number of layers than those illustrated in the drawing.

The electronic component 150 may be various types of active components and/or passive components. For example, the electronic component 150 may include an Integrated Circuit Device (ICD) and an Embedded Passive Integrated Component (EPIC), but the present disclosure is not limited thereto. The electronic component 150 may include a connection pad P in contact with a connection via of the first via layer 141. The electronic component 150 may be provided in plural, and a plurality of electronic components 150 may be identical to or different from each other.

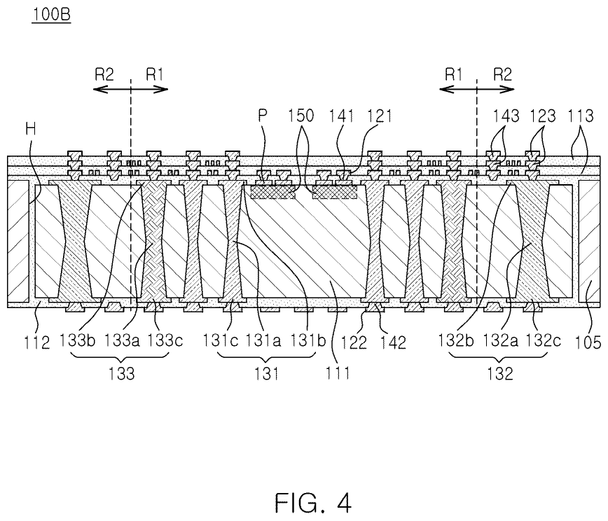

FIG. 4 is a cross-sectional view schematically illustrating another example of a printed circuit board.

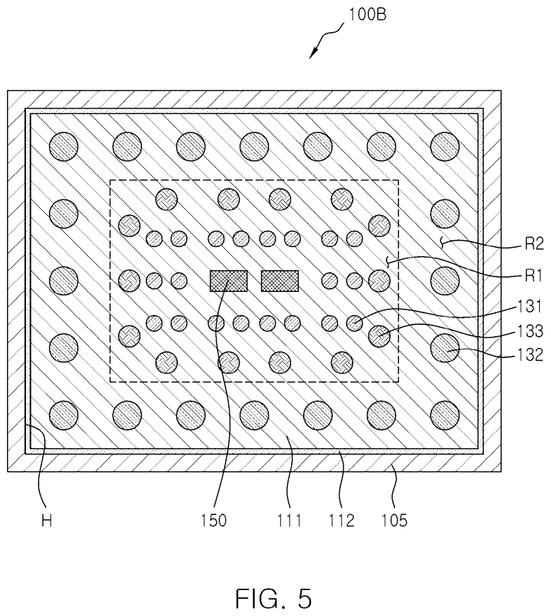

FIG. 5 is a plan view schematically illustrating a glass layer of the printed circuit board of FIG. 4 when viewed from above.

Referring to the drawings, a printed circuit board 100B according to another example embodiment may further include a plurality of third metal vias 133, in the printed circuit board 100A according to the above-described example embodiment. The plurality of third metal vias 133 may be respectively disposed in the first region R1, and may be disposed between a plurality of first metal vias 131 and a plurality of second metal vias 132. Each of the plurality of third metal vias 133 may include a third via portion 133a penetrating through the glass layer 111, a third-first pad portion 133b disposed on an upper surface (first surface) of the glass layer 111, and a third-second pad portion 133c disposed on the lower surface (second surface) of the glass layer 111. In this case, the third via portion 133a may have a maximum width (or diameter) smaller than that of the second via portion 132a in the cross-section, but may have a maximum width (or diameter) greater than that of the first via portion 131a in the cross-section. Here, the maximum width (or diameter) of each cross-section of the via may be measured, for example, using a scanning microscope or an optical microscope based on a cross-section obtained by polishing or cutting the substrate in the vertical direction, and the cut cross-section may be a cross-section obtained by cutting the central axis of each via. For example, a combination of metal vias of various sizes may be designed depending on the design purpose.

From this perspective, an average pitch between the plurality of third metal vias 133 may be smaller than an average pitch between the plurality of second metal vias 132, but greater than an average pitch between the plurality of first metal vias 131. Here, the average pitch between the metal vias may be measured, for example, using a scanning microscope or an optical microscope based on the cross-section obtained by polishing or cutting the substrate in a vertical direction, and may use an average value of pitches between adjacent metal vias. Additionally, the third-first and third-second pad portions 133b and 133c may have a smaller maximum width (or diameter) than the second-first and second-second pad portions 132b and 132c in the cross-section, but may have a greater maximum width (or diameter) than the first-first and first-second pad portions 131b and 131c in the cross-section. Here, the maximum width (or diameter) of each pad portion may be measured, for example, using a scanning microscope or an optical microscope based on a cross-section obtained by polishing or cutting the substrate in the vertical direction, and the cut cross-section may be a cross-section obtained by cutting the central axis of each pad portion. Additionally, the third-first and third-second pad portions 133b and 133c may have a smaller planar area than the second-first and second-second pad portions 132b and 132c, but may have a greater planar area than the first-first and first-second pad portions 131b and 131c. Here, the planar area of each pad portion may be measured, for example, using a scanning microscope or an optical microscope based on the cross-section obtained by polishing or cutting the substrate in the horizon direction.

Hereinafter, components of a printed circuit board 100B according to another example embodiment will be described in more detail with reference to the drawings.

The third metal via 133 may include a metal. The metal may include copper (Cu), aluminum (Al), silver (Ag), tin (Sn), gold (Au), nickel (Ni), lead (Pb), titanium (Ti), and/or alloys thereof. For example, the third metal via 133 may include a stack structure of a titanium layer and a copper layer formed by sputtering and/or electroless plating, as a seed layer. For example, third metal via 133 may include sputtered titanium and sputtered copper, sputtered titanium and chemical copper, or sputtered titanium, sputtered copper and chemical copper. Additionally, a copper layer formed by electrolytic plating based thereon may be included as a plating layer. For example, third metal via 133 may include electrolytic copper. The third metal via 133 may include a metal via for signal transmission, a metal via for power transmission, and/or a metal via for ground transmission. The third via portion 133a of the third metal via 133 may have a shape in which a side surface thereof is tapered, for example, an hourglass shape, but the present disclosure is not limited thereto, and may have a cylindrical shape in which a side surface thereof is approximately vertical. Each of the third-first and third-second pad portions 133b and 133c of the third metal via 133 may have a circular or elliptical shape on a plane, but is not limited thereto, and may have a polygonal shape if necessary. The third metal via 133 may be provided in plural.

Other descriptions may be substantially the same as those described in the printed circuit board 100A according to the above-described example embodiment.

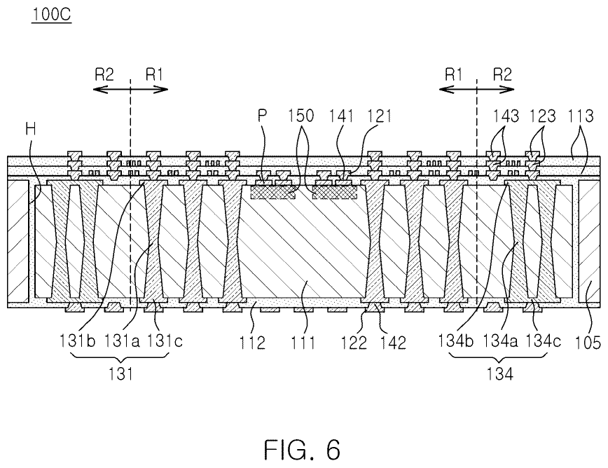

FIG. 6 is a cross-sectional view schematically illustrating another example of a printed circuit board.

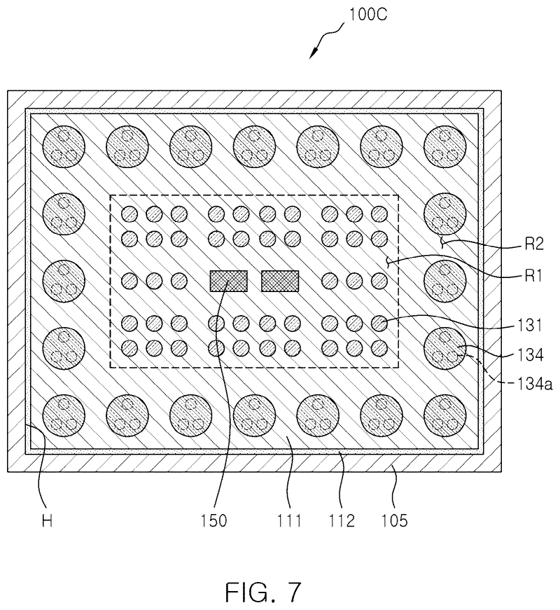

FIG. 7 is a plan view schematically illustrating a glass layer of the printed circuit board of FIG. 6 when viewed from above.

Referring to the drawings, a printed circuit board 100C according to another example embodiment may be configured so that instead of the plurality of second metal vias 132 described above, a plurality of fourth metal vias 134 may be included in the second region R2, in the printed circuit board 100A according to the above-described example embodiment. The plurality of fourth metal vias 134 may be disposed on substantially the same position as the plurality of second metal vias 132 described above, and may perform substantially the same function, but may have a different shape of the vias therefrom. For example, each of the plurality of fourth metal vias 134 may include a fourth via 134a penetrating through the glass layer 111, a fourth-first pad portion 134b disposed on the upper surface (first surface) of the glass layer 111, and a fourth-second pad portion 134c disposed on the lower surface (second surface) of the glass layer 111. In this case, the fourth via portion 134a of each of the plurality of fourth metal vias 134 may include a plurality of vias. For example, the fourth via portion 134a of each of the plurality of fourth metal vias 134 may be in the form of a plurality of vias respectively penetrating through the glass layer 111 between the fourth-first and fourth-second pad portions 134b and 134c of each of the plurality of fourth metal vias 134 and respectively connecting the fourth-first and fourth-second pad portions 134b and 134c. For example, each of the plurality of fourth metal vias 134 may have a form in which pads and vias are connected in a one-to-many relationship. In this case, the effect may be further improved by increasing a surface area of each of the plurality of fourth metal vias 134 serving as power transmission or heat dissipation.

Meanwhile, the maximum width (or diameter) of the fourth via portion 134a in the cross-section may be the sum total of the maximum widths (or diameters) in the cross-sections of each of the plurality of vias included therein. Accordingly, the fourth via 134a may also have a maximum width (or diameter) greater in the cross-section than the first via 131a, similarly to the second via 132a described above. Here, the maximum width (or diameter) of a via portion or each via in the cross-section may be measured, for example, using a scanning microscope or an optical microscope based in the cross-section obtained by vertically polishing or cutting the substrate, and the cut cross-section may be a cross-section obtained by cutting the central axis of the via portion or each via.

Hereinafter, components of a printed circuit board 100C according to another example embodiment will be described in more detail with reference to the drawings.

The fourth metal via 134 may include a metal. The metal may include copper (Cu), aluminum (Al), silver (Ag), tin (Sn), gold (Au), nickel (Ni), lead (Pb), titanium (Ti), and/or alloys thereof. For example, the fourth metal via 134 may include a stack structure of a titanium layer and a copper layer formed by sputtering and/or electroless plating, as a seed layer. For example, the fourth metal via 134 may include sputtered titanium and sputtered copper, sputtered titanium and chemical copper, or sputtered titanium, sputtered copper and chemical copper. Additionally, the fourth metal via 134 may include a copper layer formed by electrolytic plating based thereon, as a plating layer. For example, the fourth metal via 134 may include electrolytic copper. The fourth metal via 134 may include a metal via for power transmission and/or a metal via for heat dissipation. Each of the plurality of vias included in the fourth via portion 134a of the fourth metal via 134 may have a shape in which a side surface thereof is tapered, for example, an hourglass shape, but is not limited thereto, and may also have a cylindrical shape in which a surface side thereof is approximately vertical. Each of the forth-first and fourth-second pad portions 134b and 134c of the forth metal via 134 may have a circular or elliptical shape on a plane, but is not limited thereto, and may have a polygonal shape if necessary. The fourth metal via 134 may be provided in plural. The number of plural vias included in the fourth via portion 134a is not particularly limited.

Other explanations may be substantially the same as those described in the printed circuit board 100A according to the above-described example embodiment. Meanwhile, the plurality of fourth metal vias 134 of the printed circuit board 100C according to another example embodiment described above may also be applied to the printed circuit board 100B according to another example embodiment described above, instead of the plurality of second metal vias 132.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component. For example, exposing a pad by an opening may mean exposing the pad from a resist layer, and a surface treatment layer or the like may be further disposed on the exposed pad.

In the present disclosure, being disposing in a cavity or a through-portion may include not only a case in which an object is disposed completely in the cavity or the through-portion, but also a case in which the object protrudes upwardly or downwardly in a cross-section. For example, when the object is placed in the cavity or the through-portion in a plane, this may be determined in a broader sense.

In the present disclosure, determination may be performed by including process errors, positional deviations, errors at the time of measurement, which may occur substantially in a manufacturing process. For example, being substantially coplanar may include not only a complete coplanar case, but also an approximately coplanar case. In addition, being disposed on substantially the same level may include being disposed on approximately the same level as well as being disposed on completely the same level. In addition, having a substantially specific shape may include not only having a completely such shape, but also a case having approximately such a shape.

In the present disclosure, the same insulating material may denote not only a case of being the same insulating material, but also a case of including the same type of insulating material. Accordingly, the composition of the insulating material is substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points. Other methods and/or tools appreciated by one of ordinary skill in the art, even if not described in the present disclosure, may also be used.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a glass layer including a first region, and a second region surrounding the first region;
a plurality of first metal vias spaced apart from each other in the first region and respectively including a first via portion penetrating through the glass layer; and
a plurality of second metal vias spaced apart from each other in the second region and respectively including a second via portion penetrating through the glass layer,
wherein, in a cross-section of the printed circuit board, the first via portion has a maximum width that is smaller than a maximum width of the second via portion.

2. The printed circuit board according to claim 1,
wherein an average pitch of the plurality of first metal vias is smaller than an average pitch of the plurality of second metal vias.

3. The printed circuit board according to claim 1,
wherein the first region includes a portion adjacent to a center of the glass layer, and
the second region includes a portion adjacent to an edge of the glass layer.

4. The printed circuit board according to claim 1,
wherein each of the plurality of first metal vias includes a metal via configured to transmit signal, and
each of the plurality of second metal vias includes a metal via configured to transmit power or a metal via configured to dissipate heat.

5. The printed circuit board according to claim 1, further comprising:
an electronic component embedded in the first region of the glass layer,
wherein the plurality of first metal vias are respectively disposed around the electronic component.

6. The printed circuit board according to claim 1, further comprising:
a plurality of third metal vias spaced apart from each other in the first region and respectively including a third via portion penetrating through the glass layer,
wherein the plurality of third metal vias are disposed between the plurality of first metal vias and the plurality of second metal vias, and
in the cross-section of the printed circuit board, the third via portion has a maximum width that is smaller than the maximum width of the second via portion and larger than the maximum width of the first via portion.

7. The printed circuit board according to claim 6,
wherein an average pitch of the plurality of third metal vias is smaller than an average pitch of the plurality of second metal vias but greater than an average pitch of the plurality of first metal vias.

8. The printed circuit board according to claim 1, further comprising:
a frame having a through-portion, wherein at least a portion of the glass layer is disposed in the through-portion;
a first insulating layer covering a first surface and a second surface of the frame, and a first surface and a second surface of the glass layer, and filling a space between the frame and the glass layer in the through-portion;
a first wiring layer disposed on a first surface of the first insulating layer;
a first via layer penetrating through a first side of the first insulating layer and including a plurality of first connection vias respectively connecting the first wiring layer to the plurality of first metal vias and the plurality of second metal vias;
a second wiring layer disposed on a second surface of the first insulating layer; and
a second via layer penetrating through a second side of the first insulating layer and including a plurality of second connection vias respectively connecting the second wiring layer to the plurality of first metal vias and the plurality of second metal vias.

9. The printed circuit board according to claim 8, further comprising:
a plurality of second insulating layers disposed on the first surface of the first insulating layer;
a plurality of third wiring layers respectively disposed on first surfaces of the plurality of second insulating layers; and
a plurality of third via layers penetrating through the plurality of second insulating layers and respectively connected to one or more third wiring layer among the plurality of third wiring layers.

10. The printed circuit board according to claim 1, wherein each of the plurality of second metal vias includes a plurality of vias.

11. The printed circuit board according to claim 1, wherein, in a plan view of the printed circuit board, the plurality of second metal vias surrounds the plurality of the first metal vias.

12. The printed circuit board according to claim 6, wherein, in a plan view of the printed circuit board, the plurality of third metal vias surrounds the plurality of the first metal vias.

13. A printed circuit board, comprising:
a glass layer including a first region, and a second region surrounding the first region;
a first metal via disposed in the first region, and including a first via portion penetrating through the glass layer, a first-first pad portion disposed on a first surface of the glass layer, and a first-second pad portion disposed on a second surface of the glass layer; and
a second metal via disposed in the second region, including a second via portion penetrating through the glass layer, a second-first pad portion disposed on the first surface of the glass layer, and a second-second pad portion disposed on the second surface of the glass layer,
wherein, in a cross-section of the printed circuit board, the first-first pad portion has a maximum width that is smaller than a maximum width of the second-first pad portion.

14. The printed circuit board according to claim 13,
wherein, in the cross-section of the printed circuit board, the first-second pad portion has a maximum width that is smaller than a maximum width of the second-second pad portion in the cross-section.

15. The printed circuit board according to claim 14,
wherein the first-first pad portion has a planar area that is smaller than a planar area of the first-second pad portion, and
the first-second pad portion has a planar area that is smaller than a planar area of the second-second pad portion.

16. The printed circuit board according to claim 13, further comprising:
a third metal via disposed in the first region, and including a third via portion penetrating through the glass layer, a third-first pad portion disposed on the first surface of the glass layer, and a third-second pad portion disposed on the first surface of the glass layer,
wherein the third metal via is disposed between the first and second metal vias, and
in the cross-section of the printed circuit board:
the third-first pad portion has a maximum width that is smaller than the maximum width of the second-first pad portion and greater than the maximum width of the first-first pad portion, and
the third-second pad portion has a maximum width that is smaller than a maximum width of the second-second pad portion and greater than a maximum width of the first-second pad portion.

17. The printed circuit board according to claim 16,
wherein the third-first pad portion has a planar area that is smaller than a planar area of the second-first pad portion and greater than a planar area of the first-first pad portion, and
the third-second pad portion has a planar area that is smaller than a planar area of the second-second pad portion and greater than a planar area of the first-second pad portion.

18. The printed circuit board according to claim 13,
wherein the second via portion includes a plurality of vias respectively penetrating through the glass layer between the second-first and second-second pad portions and connecting the second-first and second-second pad portions, respectively.
